(19) United States
(12) Patent Application Publication
(10) Pub. No.: US 2024/0332088 A1
(43) Pub. Date: Oct. 3, 2024

(54) MODULATION OF CHIP PERFORMANCE BY CONTROLLING TRANSISTOR GATE PROFILE

(71) Applicant: Intel Corporation, Santa Clara, CA (US)

(72) Inventors: Reza Bayati, Portland, OR (US); Swapnadip Ghosh, Hillsboro, OR (US); Chiao-Ti Huang, Portland, OR (US); Matthew Prince, Portland, OR (US); Jeffrey Miles Tan, Hillsboro, OR (US); Ramy Ghostine, Portland, OR (US); Anupama Bowonder, Portland, OR (US)

(73) Assignee: Intel Corporation, Santa Clara, CA (US)

(21) Appl. No.: 18/129,617

(22) Filed: Mar. 31, 2023

(51) Int. Cl. H01L 21/8234; H01L 21/3213; H01L 27/088; H01L 29/06; H01L 29/423; H01L 29/66; H01L 29/775

(52) U.S. Cl. CPC H01L 21/823456; H01L 21/32136; H01L 21/32139; H01L 21/823412; H01L 27/088; H01L 29/0673; H01L 29/42392; H01L 29/66439; H01L 29/775

(57) ABSTRACT

One or more transistors may have gate structures with differing sidewall slopes. The gate structures may be over stacks of channel regions in nanosheets (or nanoribbons or nanowires), and the differing gate profiles may correspond to differing electrical characteristics. Transistors with metal gate structures may be tuned by strategically etching the gate structures, for example, using lower etch powers, higher etch temperatures, and/or longer etch durations, to achieve substantially vertical gate profiles.

### BACKGROUND

Historically, chip suppliers have typically maximized integrated circuit (IC) electrical performance of a product by changing the design, including the layout, of various circuits and/or the materials used in the manufacture of the product. Changing the design generally requires several rounds of tape out, and fabrication process steps may need to be updated to deliver the new layouts. Changing a material may introduce many complications, such as the necessity of changing or adding other materials in a materials stack, as integration processes have to be modified to accommodate the new materials. Other structures and techniques are needed to enable IC improvements without expensive and prolonged redesigns.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A and 1B illustrate cross-sectional profile views of transistors, including gate structures around stacks of nanosheets, in various stages of manufacture, in accordance with some embodiments;

FIGS. 2A and 2B illustrate cross-sectional profile and plan views of transistors, including stacks of channel regions within nanosheets and gate structures having sloped sidewalls, in accordance with some embodiments;

FIGS. 3A and 3B illustrate cross-sectional profile and plan views of transistors, including stacks of channel regions within nanosheets and gate structures having substantially vertical sidewalls, in accordance with some embodiments;

FIGS. 4A and 4B illustrate cross-sectional profile and plan views of transistors, including stacks of channel regions within nanosheets and gate structures having sidewalls with a negative or reverse taper, in accordance with some embodiments;

FIGS. 5A and 5B illustrate schematic views of an exemplary reactive plasma processing chamber, in accordance with some embodiments;

FIG. 6 is a flow chart of methods for tuning electrical parameters of transistors with metal gate structures, in accordance with some embodiments;

FIG. 7 is a flow chart of methods for etching a transistor's metal gate structure, in accordance with some embodiments;

FIG. 8 is a flow chart of methods for etching a transistor's metal gate structure, in accordance with some embodiments;

FIG. 9 illustrates a diagram of an example data server machine employing an IC device having a transistor tuned by a metal gate etch, in accordance with some embodiments; and

FIG. 10 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over.” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Structures and techniques are disclosed to improve the performance of integrated circuit (IC) devices with metal gates by tuning the transistors of an IC device, rather than redesigning the IC device. The device's electrical performance can be modulated without changing the layout, but instead optimizing based on the target application of that specific product. Electrical performance can be tuned, without affecting other steps in the integration flow, by controlling the transistor's metal gate cut profile. For example, by etching metal gate structures, device capacitances may be reduced and ring oscillator frequencies increased, even while maintaining target drive and leakage currents. Threshold voltages (and so drive and leakage currents) can be shifted with these etch processes. This tuning method can properly balance performance and cost without requiring new or different photomask sets or materials. Higher-end products can be manufactured with the same photomask set (i.e., design or layout) as a less-expensive product by making higher quality gate etches to otherwise identical transistors. Less expensive products can be manufactured with the same layout and at appropriate manufacturing costs.

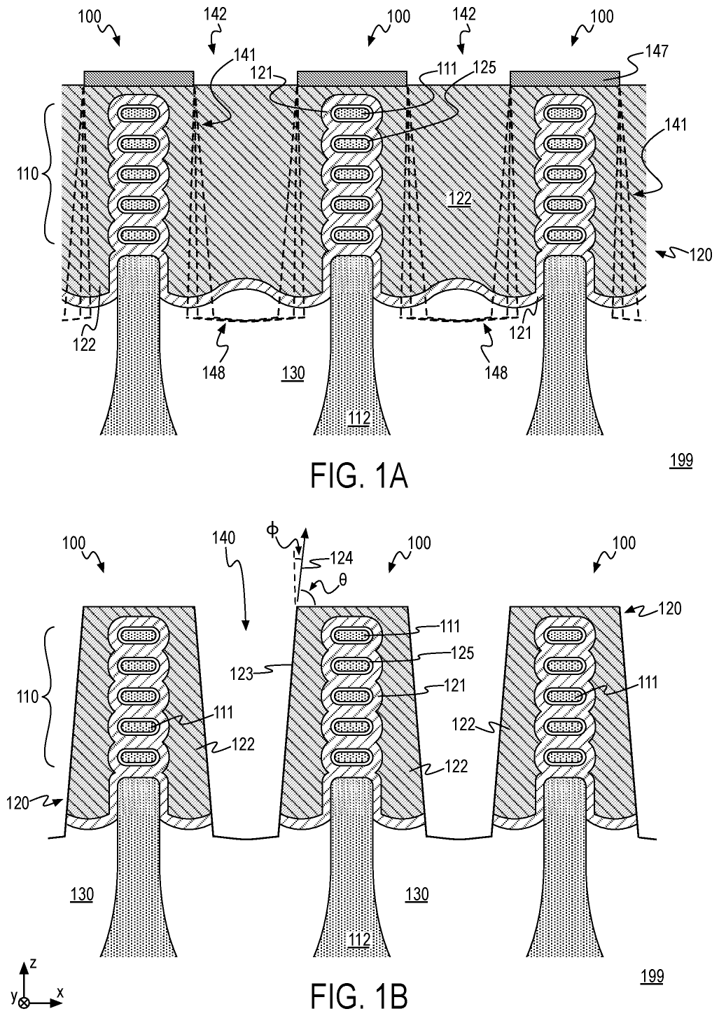

FIGS. 1A and 1B illustrate cross-sectional profile views of transistors 100, including gate structures 120 around stacks 110 of nanosheets 111, in various stages of manufacture, in accordance with some embodiments. FIG. 1A shows multiple stacks 110 of nanosheets 111, each over a fin 112, within a shared gate structure 120. FIG. 1B shows stacks 110 of nanosheets 111, each stack within a discrete gate structure 120, for example, after a metal gate cut has separated a common gate structure 120 into separate structures 120 for each transistor 100.

Nanosheets 111 include transistor channel regions that extend longitudinally in the y directions and couple to source and drain regions in front of and behind the viewing plane. Nanosheets 111 are vertically aligned in stacks 110 over fins 112 of a same material as nanosheets 111. Although the channel regions are within nanosheets 111 in the illustrative embodiment, transistors 100 may include channel regions within fins 112, which may be continuous to the top of stacks 110, rather than broken into nanosheets 111. In some embodiments, nanosheets 111 are in stacks 110 not over fins 112. Although the channel regions are within nanosheets 111 here, transistors 100 may include channel regions within nanowires or nanoribbons. Nanosheets 111 may be wider or narrower (e.g., in the x direction), and the term “nanosheet” elsewhere herein may also refer to nanowires or nanoribbons, which may be similar to nanosheets 111, but narrower in the x direction. For example, nanosheets 111 may be wider or narrower in transistors 100 with more or less drive current, respectively. Nanosheets 111 (and the channel regions within nanosheets 111) and fins 112 are of monocrystalline silicon (Si). In other embodiments, nanosheets 111 are of one or more other semiconductor materials, such as germanium (Ge), silicon germanium (SiGe), or a III-V material (e.g., gallium arsenide (GaAs), gallium nitride (GaN), etc.).

Gate structure 120 includes a gate dielectric layer 125. Gate dielectric layer 125 is over and around nanosheets 111 (on all sides) and insulates nanosheets 111 from a gate liner metal 121. In embodiments with channel regions within fins 112, gate dielectric layer 125 is over and on either side of channel regions in fins 112. In the embodiment of FIGS. 1A and 1B, gate dielectric layers 125 have a thickness of 1 nm. In other embodiments, gate dielectric layer 125 has a thickness between about 1 and 2 nm. In other embodiments, for example, to support higher voltages, gate dielectric layer 125 has a thickness greater than 2 nm, e.g., up to about 10 nm. In some embodiments, gate dielectric layer 125 includes multiple layers within layer 125, for example, a high-permittivity (“high-K”) dielectric material in one layer and a lower permittivity material in another layer. Gate dielectric layer 125 may include a mixture of dielectric materials, including one or more high-K dielectric materials. Gate dielectric layer 125 may include elements such as hafnium, silicon, oxygen, titanium, tantalum, lanthanum, aluminum, zirconium, barium, strontium, yttrium, lead, scandium, niobium, and zinc. Examples of high-K materials that may be used in gate dielectric layer 125 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate.

Gate structure 120 may include multiple materials, for example, in multiple layers, on and over gate dielectric layer 125. Gate structure 120 may include at least one of a p-type work function metal or an n-type work function metal, depending on whether the transistor is a PMOS or an NMOS transistor. In the illustrative embodiments, gate structure 120 includes a stack of two or more metal layers, where one or more metal layers are work function metal layers (including at least gate liner metal 121), and at least one metal layer is a fill metal layer (including at least gate bulk metal 122). For a PMOS transistor, metals that may be used for the gate electrode include, but are not limited to, ruthenium, palladium, platinum, cobalt, nickel, and conductive metal oxides, e.g., ruthenium oxide. A p-type metal layer enables the formation of a PMOS gate electrode with a work function that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals, such as hafnium carbide, zirconium carbide, titanium carbide, and tantalum carbide. An n-type metal layer enables the formation of an NMOS gate electrode with a work function that is between about 3.9 eV and about 4.2 eV.

Transistors 100 are on or in a substrate 199. Substrate 199 may be of any suitable material(s), including a crystalline material. For example, substrate 199 may be or include an IC die of any suitable semiconductor or other material. Substrate 199 may be of or include the material of nanosheets 111 and/or fins 112 on or in substrate 199 (such as previously described semiconductors Si, Ge, SiGe, GaAs, GaN, etc.). Substrate 199 may be of or include one or more other materials, for example, an insulator material (such as sapphire (e.g., Al₂O₃)) or semiconductor material (such as silicon carbide (e.g., SiC)). Substrate 199 may also include metals, dielectrics, dopants, and other materials commonly found in semiconductor substrates.

An electrical isolation 130, such as a shallow-trench isolation (STI), is over substrate 199, between fins 112 and transistors 100. Isolation 130 may prevent or minimize leakage current between adjacent devices or components on substrate 199, such as transistors 100, whose source and drain regions may be aligned (e.g., in the y directions) with channel regions within nanosheets 111. Isolation 130 may be or include any suitable electrically insulating material, for example, an oxide (e.g., of silicon, such as silicon dioxide (SiO₂)). An STI or other isolation 130 may have a height of tens of nanometers, which may depend on a height of fins 112 (or whether channel regions are in or over fins 112 or not, or whether fins 112 are present). In some embodiments, an STI has a height of about 50 nm. Isolation 130 may provide a platform for the deposition of other materials, such as those of gate metals 121, 122.

Gate metals 121, 122 are over isolation 130 and couple transistors 100 with shared gate structure 120. Gate liner metal 121 is conformally on all gate dielectric layers 125 over the three stacks 110 of nanosheets 111. Gate fill metal 122 is over (e.g., above and on either side of) each stack 110 of nanosheets 111, gate dielectric layer 125, and gate liner metal 121. In some embodiments, gate fill metal 122 is between liner metal 121 (between nanosheets 111 and dielectric layers 125). Gate metals 121, 122 of common gate structure 120 may continue to one or both sides (e.g., in the x directions) and may enclose other stacks 110 of nanosheets 111 (with gate dielectric layer 125) to either side of the visible portion of the cross-sectional view of FIG. 1A.

Stacks 110 of channel-region nanosheets 111 share gate structure 120, but transistors 100 may be independently controlled by separate gate structures 120, for example, if shared gate structure 120 were divided by an etch. In FIG. 1A, etch mask 147 is over stacks 110, and openings 142 in mask 147 are between stacks 110. Various potential etch edges 141 are shown with dashed lines extending from and below openings 142. Etch bottoms or etch stops 148 show potential bottom edges of a metal gate cut through gate structure 120. In some embodiments, etch stops 148 are at an upper surface of isolation 130. For example, an etch may be of metals 121, 122 and may not extend into isolation 130.

FIG. 1B shows transistors 100 with discrete gate structures 120 for each of stacks 110, for example, after a metal gate cut of and through metals 121, 122 between stacks 110 has separated a common gate structure 120 into separate structures 120 for each transistor 100. Gate structures 120 have sidewalls 123. Sidewall 123 and its tangent vector 124 have a slope that can be characterized by an elevation angle θ (e.g., up from the x-y plane) or a depression angle ϕ (e.g., down from the vertical, z axis) as shown with sidewall tangent vector 124 (extending from, and in the same direction as, sidewall 123). In some embodiments, angles θ, ϕ vary somewhat between different points (e.g., at different z-heights) along sidewall 123. A cavity or void 140 between adjacent gate structures 120 separates transistors 100. Void 140 may be filled with an insulator, such as a low-K dielectric material. In some embodiments, one or more electric lines are located in an insulator between transistors 100 and within void 140.

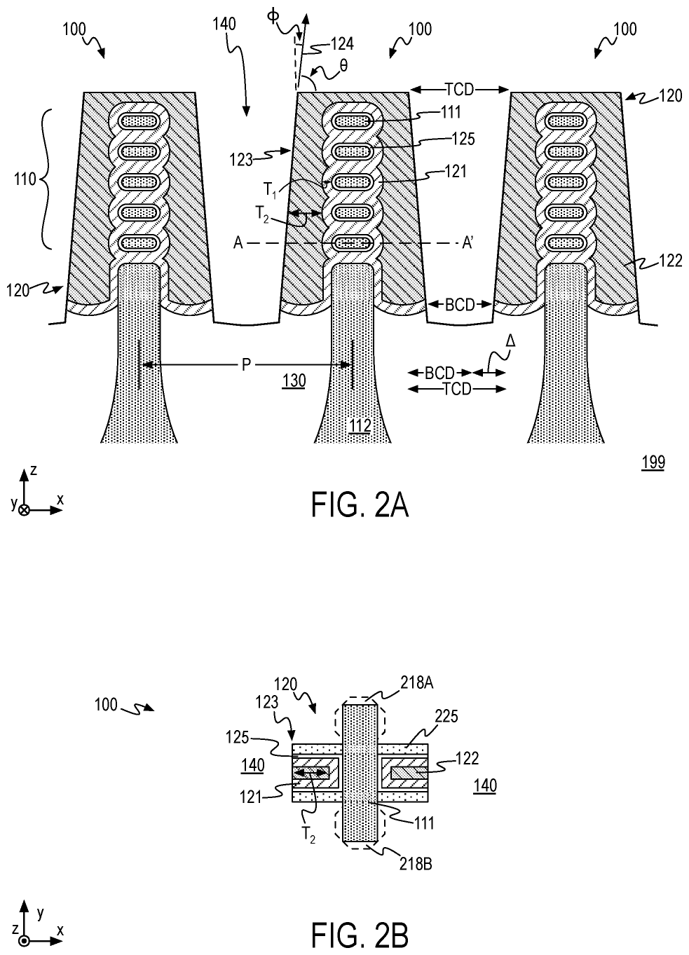

FIGS. 2A and 2B illustrate cross-sectional profile and plan views of transistors 100, including stacks 110 of channel regions within nanosheets 111 and gate structures 120 having sloped sidewalls 123, in accordance with some embodiments. FIG. 2A shows transistors 100 substantially as described at FIGS. 1A and 1B. FIG. 2B illustrates a cross-sectional plan view of transistor 100 at line A-A′ of FIG. 1A, including a cross-section of gate structure 120 and nanosheet 111.

Various critical dimensions (CDs) and other dimensions of transistors 100 are shown in FIG. 2A. Void 140 can be characterized by top and bottom CDs TCD, BCD, which are the upper and lower distances between adjacent gate structures 120, and by a taper Δ, which is a difference between top and bottom CDs TCD, BCD. Top and bottom CDs TCD, BCD are measured between the upper and lower points on sidewall 123. A large taper Δ corresponds to sidewall 123 having a shallower slope (e.g., a lower elevation angle θ and larger depression angle ϕ). A center-to-center pitch P is between adjacent transistors 100 (and channel regions, nanosheets 111, and fins 112) and may be substantially fixed (for example, independent of an etch process, to achieve a desired device count and device density for a die footprint constraint). Gate liner metal 121 has a thickness T₁ around gate dielectric layer 125 and between dielectric layer 125 and gate bulk metal 122. Gate bulk metal 122 has a thickness T₂ between gate liner metal 121 and sidewall of gate structure 120, e.g., on either side of stack 110 of channel regions and nanosheets 111. Gate liner metal 121 may be substantially conformal over gate dielectric layer 125, so thickness T₁ may be substantially consistent throughout gate structure 120. For a given pitch P, larger top and bottom CDs TCD, BCD correspond to a narrower gate structure 120 and a shorter thickness T₂ of gate bulk metal 122.

For a given pitch P, larger top and bottom CDs TCD, BCD mean that narrower gate structures 120 are separated further. Greater separation between gate structures 120 reduces a gate capacitance of transistor 100, as well as a capacitance between adjacent transistors 100. A capacitance between adjacent transistors 100 or various nodes in a circuit may be referred to as an effective capacitance, which may combine together the effects multiple capacitances, e.g., parasitic capacitances, at a certain node or structure. Reduced effective capacitance for or between transistors 100 may result in reduced resistive-capacitive (RC) delays and faster circuits (e.g., that may run at higher frequencies). For example, a ring oscillator (or other signal source) on an IC die (e.g., substrate 199) having transistors 100 with reduced gate capacitances may have a correspondingly increased output frequency. Reduced capacitance for or between transistors 100 may also correspond to reduced “cross talk” (e.g., unwanted signal transmission) between adjacent but not connected transistors 100. In some embodiments, even with different etch process available, top CD TCD between upper edges of adjacent gate structures 120 is relatively fixed by the openings in an etch mask over substrate 199 and transistors 100. In such embodiments, reduced capacitances may correspond with larger bottom CDs BCD and smaller tapers A.

In some embodiments, the illustrative embodiment of FIG. 2A has satisfactory electrical performance with elevation angle θ of 84° (and depression angle ϕ from vertical of 6°). In an exemplary embodiment, with a pitch P of about 120 nm, top CD TCD is 48.9 nm, bottom CD BCD is 36.2 nm, and taper Δ is 12.7 nm. The satisfactory electrical performance with the provided top and bottom CDs TCD, BCD may include a satisfactorily high ring oscillator frequency due to sufficiently low gate capacitances. The satisfactory electrical performance of the illustrative embodiment may be the result of a relatively quick and inexpensive etch process to form gate structures 120. Such an etch process may balance various electrical performance parameters with various processing costs (such as wafer processing steps and wafer processing time) and other considerations. Other similar embodiments (e.g., similarly processed or similarly performing) may have similarly moderate sidewall slopes, for example, with elevation angles θ of up to 87° (and depression angles ϕ of 3° and larger).

FIG. 2B illustrates a cross-sectional plan view of transistor 100, including nanosheet 111 with channel region and within gate structure 120. Nanosheet 111 extends in the y directions through gate structure 120 and a spacer dielectric 225 on either side of gate structure 120. Gate dielectric layer 125 is conformally around nanosheet 111 and on spacer dielectric 225. Spacer dielectric 225 is an insulator, such as a low-K dielectric, between gate structure 120 and source and drain regions 218A, 218B. The channel regions and nanosheets 111 extend longitudinally in the y directions. In the illustrative embodiment, transistor 100 includes a source or drain region 218A coupled to a first longitudinal end of the channel regions in nanosheets 111 and a source or drain region 218B coupled to a second longitudinal end of the channel regions in nanosheets 111. Source and drain structures 218A, 218B are conductive structures, e.g., of a metal. Source and drain structures 218A, 218B may be of semiconductor material having the opposite conductivity type with respect to channel regions within nanosheets 111. In some embodiments, source and drain structures 218A, 218B are semiconductor materials doped with the pertinent conductivity type dopants. In other embodiments, a source structure and drain structure are epitaxially grown from channel regions within nanosheets 111. In such embodiments, the source and drain structures are blocks (or faceted blocks) of material that do not match the shape of nanosheets 111.

Gate structure 120 is between source and drain regions 218A, 218B. Gate liner metal 121 is conformally around gate dielectric layer 125 (around nanosheet 111) and on gate dielectric layer 125 on spacer dielectric 225. Gate fill metal 122 is laterally between layers of gate liner metal 121 (in the y direction), and gate liner metal 121 is also between fill metal 122 and the channel region of nanosheet 111 (and gate dielectric layer 125). Gate liner metal 121 being conformally on and within gate dielectric layer 125, the thickness of liner metal 121 in the y direction is substantially equal to thickness T₁ of liner metal 121 in the x direction. Gate fill metal 122 is then between two thicknesses T₁ of liner metal 121 in the y direction and limited in that dimension by the gate length. Thickness T₂ and so the volume of fill metal 122 is then determined by the shape of void 140, e.g., top and bottom CDs TCD, BCD. Thickness T₂ of fill metal 122 varies with z-height along gate structure 120. Thickness T₂ of fill metal 122 at line A-A′ (at the lowest nanosheet 111) is greater than at other nanosheets 111 in transistor 100.

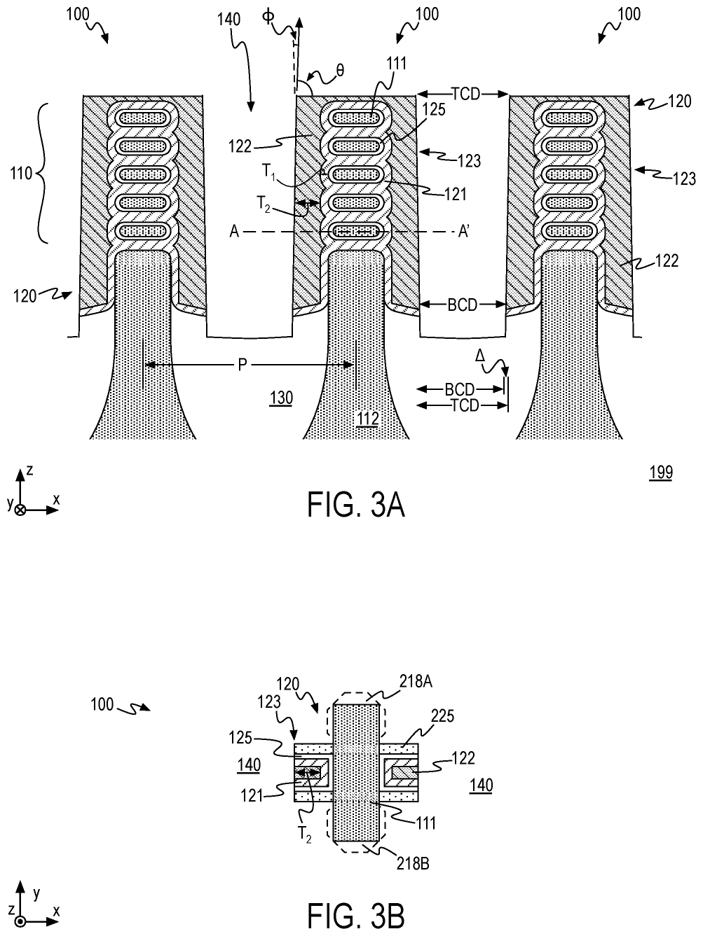

FIGS. 3A and 3B illustrate cross-sectional profile and plan views of transistors 100, including stacks 110 of channel regions within nanosheets 111 and gate structures 120 having substantially vertical sidewalls 123, in accordance with some embodiments. Substrate 199 may be an IC die similar to substrate 199 in the embodiment of FIGS. 2A, 2B and with similar transistors 100 and a same center-to-center pitch P between adjacent transistors 100. Notably, top and bottom CDs TCD, BCD are approximately equal in FIG. 3A (and top CDs TCD are substantially constant between FIGS. 2A and 3A). Voids 140 between gate structures 120 are wider (e.g., at least at bottom CD BCD), and thicknesses T₂ of gate fill metal 122 are correspondingly shorter, particularly at lower z-heights of gate structure 120. Bottom CD BCD is as great, or nearly as great, as top CD TCD, which corresponds to a minimal taper Δ (e.g., of approximately zero). Given the same center-to-center pitch P and that bottom CD BCD is approximately equal to top CD TCD, void 140 is open wider at bottom CD BCD in the example of FIG. 3A. In the example of FIG. 3A, the nearest adjacent sidewall 123 to sidewall 123 of a given transistor 100 is a greater distance (e.g., a portion of pitch P) than a distance between nearest adjacent sidewalls 123 of the same pair of transistors 100 (e.g., with the same pitch P) in the example of FIG. 2A (e.g., from the same design or photomask set). In some embodiments, an electrical line (or other structure) is in void 140 between transistors 100, and there is a greater distance between an adjacent structure and transistor 100 (e.g., sidewall 123) in the example of FIG. 3A than the corresponding distance (between an adjacent structure and transistor sidewall 123) in the example of FIG. 2A. Sidewalls 123 are substantially vertical, for example, with elevation angle θ of 89.5° (and depression angle ϕ from vertical of 0.5°). In some embodiments, transistors 100 have an elevation angle θ of 90° (and depression angle ϕ from vertical of 0°), and taper Δ is 0 nm. FIG. 3B illustrates a cross-sectional plan view of transistors 100 with the notably shorter thickness T₂ of gate fill metal 122. The shorter thicknesses T₂ of fill metal 122 in gate structure 120 corresponds to a correspondingly lower volume of fill metal 122 in in gate structure 120 and around stacks 110 of channel regions in nanosheets 111.

In some embodiments, the illustrative embodiment of FIG. 3A has an improved electrical performance relative to the embodiment of FIG. 2A due to increased spacing and substantially lower gate capacitances. In an exemplary embodiment, with a pitch P of about 120 nm, top CD TCD is 46.5 nm, bottom CD BCD is 46.2 nm, and taper Δ is 0.26 nm. In some embodiments, the improved electrical performance with the provided top and bottom CDs TCD, BCD includes a higher ring oscillator frequency due to reduced gate (and other) capacitances. In some such embodiments, the ring oscillator frequency is 2% higher than the embodiment of FIG. 2A (with a taper Δ of 12.7 nm and elevation angle θ of 84°). In some such embodiments, the ring oscillator frequency is 3% higher than the embodiment of FIG. 2A. The improved electrical performance of the illustrative embodiment may be the result of a slower and costlier etch process to form gate structures 120. Such an etch process may achieve steeper sidewalls 123 (e.g., with elevation angles θ of greater than 87°) and various improvements in electrical performance parameters at the expense of increased processing costs (such as additional wafer processing steps and/or wafer processing time), but without the need for a new design (and associated lithographic masks) or new materials.

In some embodiments, the illustrative embodiment of FIG. 3A has an improved electrical performance relative to the embodiment of FIG. 2A due to improved threshold voltage (Vₜₕ) related to the size and shape of gate structure 120 (and so voids 140). The size and shape of gate structure 120 may affect the Vₜₕ due to the relative amounts and dimensions of the constituent metals in gate structure 120. Gate structure 120 may include a plurality of layers, including at least liner metal 121 and bulk metal 122 to effectuate electrostatic gate control. For example, gate structure 120 may include primary- and secondary-work function layers. In some embodiments, gate liner metal 121 is a primary-work function layer, and bulk metal 122 is a secondary-work function layer. In some embodiments, gate liner metal 121 includes primary- and secondary-work function layers. Additional work-function layers may be used. Example work-function materials in an NMOS primary-work function layer include, but are not limited to, hafnium, zirconium, titanium, tantalum, aluminum, alloys of these metals, and carbides of these metals such as hafnium carbide, zirconium carbide, titanium carbide, and tantalum carbide, and nitrides such as tantalum nitride and titanium nitride. A secondary-work function layer, directly adjacent to the primary-work function layer, includes a material that has a different work function as compared to the work function of the primary-work function layer. Example work function materials in a primary-work function layer include, but are not limited to, ruthenium, palladium, platinum, cobalt, nickel, molybdenum, or tungsten, and associated nitrides or carbides of tungsten, ruthenium or molybdenum.

In some embodiments, gate structure 120 includes a particular arrangement of work-function layers to provide a desired Vₜₕ and/or to enable tuning of Vₜₕ in transistor 100. The Vₜₕ of transistors 100 may correspond to the relative amounts (e.g., thicknesses T₁, T₂) and locations of work-function materials in gate structure 120, which enables the tuning of Vₜₕ by etching away a greater or lesser thickness T₂ of fill metal 122. In some such embodiments, gate liner metal 121 is a primary-work function layer (or includes a work-function layer portion) adjacent to gate dielectric layer 125 around the channel regions in nanosheets 111, and the primary-work function layer is between a secondary-work function layer and gate dielectric layer 125. In some such embodiments, gate fill metal 122 is the secondary-work function layer. In some embodiments, a Vₜₕ tuning shift of ˜30 mV corresponds to a range of a ratio of thicknesses T₂:T₁ of around 2.5 or 3. For example, Vₜₕ can be tuned over a range of 30 mV by varying thickness T₂ (e.g., by etching) of fill metal 122 from a very thin layer (and a ratio of thicknesses T₂:T₁ of more than zero, but less than one) to a layer about three times as thick as liner metal 121 (and a ratio of thicknesses T₂:T₁ of about three). In this way, Vₜₕ can be tuned without altering a doping profile in nanosheets 111 and associated channel regions, without altering gate dielectric layer 125, and without the need for new lithographic masks or new materials. In some embodiments, a first transistor 100 on a first substrate 199 with a substantially vertical sidewall 123 (having taper Δ of less than 3 nm and elevation angle θ of 90°±1°) has a lower Vₜₕ than a second transistor 100 having a flatter slope of sidewall 123 (with elevation angle θ more than 5° lower). In some such embodiments, the second transistor 100 is on a second substrate 199.

The tuning of Vₜₕ also enables the tuning of other dependent parameters, such as drive current and leakage current. While an optimal Vₜₕ for some applications may correspond to higher drive currents, yet other applications may be optimized with a Vₜₕ corresponding to lower drive and leakage currents. Such decisions and optimizations need not be constrained by a requirement of a new design and mask set.

FIG. 3B illustrates a cross-sectional plan view of transistor 100, including gate structure 120 with less gate fill metal 122, as evidenced by a shorter or thinner thickness T₂. Transistors 100 have the same pitch P as transistors 100 in FIGS. 2A and 2B, but voids 140 (and bottom CDs BCD) are larger between transistors 100, and so gate structures 120 are smaller. Notably, the view of FIG. 3B is taken at line A-A′ of FIG. 3A, which is through the lowest nanosheets 111. In the embodiment of FIG. 3B, taper Δ is approximately 0 nm, and thicknesses T₂ of fill metal 122 are about equal at all z-heights. In the embodiment of FIG. 2B, taper Δ is approximately 13 nm, and the shortest thicknesses T₂ are at the lowest Z-heights. These differences highlight how voids 140 with different tapers A can skew thicknesses T₂ and so the relative conduction up and down stacks 110 of channel regions and transistors 100. Further, along with the arrangement of work-function layers in gate structure 120 generally, this conduction dependence with z-height on tapers A specifically allows for a balancing or compensation of various parameters (e.g., gate capacitance and Vₜₕ (and so drive currents, for example)) with various etch processes. This tuning and balancing of electrical parameters are available without the need for new photolithographic masks or new materials.

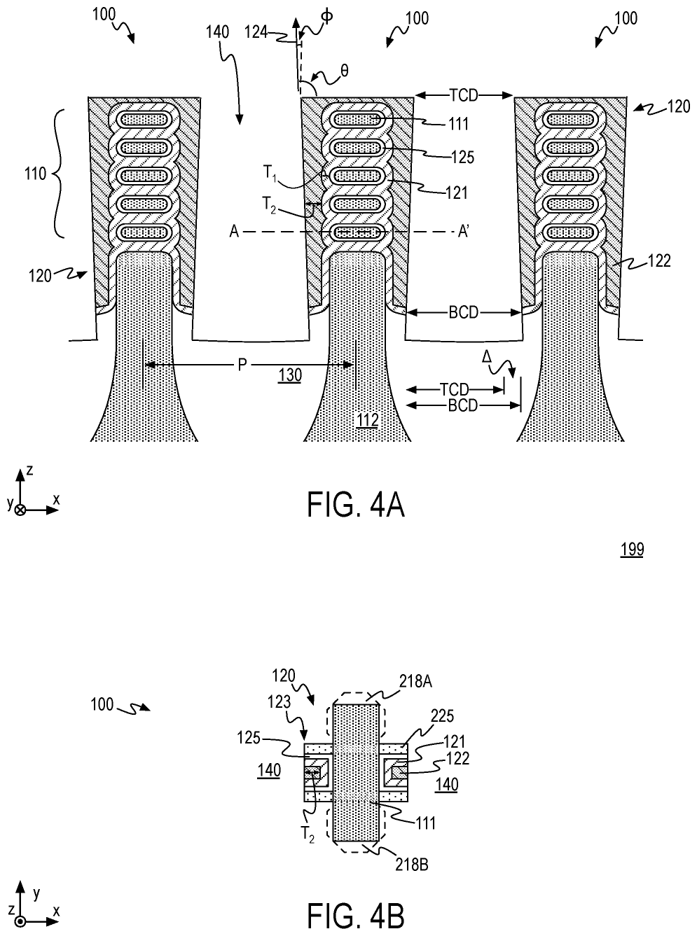

FIGS. 4A and 4B illustrate cross-sectional profile and plan views of transistors 100, including stacks 110 of channel regions within nanosheets 111 and gate structures 120 having sidewalls 123 with a negative or reverse taper Δ, in accordance with some embodiments. Substrate 199 may be an IC die similar to substrate 199 in the embodiments of FIGS. 2A-3B and with similar transistors 100 and a same center-to-center pitch P between adjacent transistors 100. Top CDs TCD are substantially constant between FIGS. 2A, 3A, and 4A. Notably, bottom CDs BCD are greater than top CDs TCD, and so taper Δ (the difference between top and bottom CDs TCD, BCD) is negative. Voids 140 between gate structures 120 are wider than even the embodiments of FIGS. 3A, 3B (e.g., at least at bottom CD BCD), and thicknesses T₂ of gate fill metal 122 are correspondingly shorter, particularly at lower z-heights of gate structure 120. The slope of sidewall 123 (and sidewall tangent vector 124) is beyond vertical with elevation angle θ greater than 90° (and depression angle ϕ of less than 0°). In some embodiments, the slope of sidewall 123 is beyond vertical with an elevation angle θ of 92° and depression angle ϕ of −2°. (Elevation angle θ may be defined as between two sides or rays, the first a ray in the horizontal plane of the top CD TCD measurement, at or above gate structure 120 and pointing away from the corresponding void 140, and the second ray being sidewall tangent vector 124. Depression angle ϕ is down from the vertical z axis, such that ϕ=90°−θ, so that is less than 0° for θ greater than 90°.)

Given a set center-to-center pitch P between adjacent transistors 100 and substantially constant top CDs TCD, a reverse taper Δ allows for larger voids 140 and greater separation between transistors 100. Given the same center-to-center pitch P and that bottom CD BCD is greater top CD TCD, void 140 is open wider at bottom CD BCD in the example of FIG. 4A. In the example of FIG. 4A, the nearest adjacent sidewall 123 to sidewall 123 of a given transistor 100 is a greater distance (e.g., a portion of pitch P) than a distance between nearest adjacent sidewalls 123 of the same pair of transistors 100 (e.g., with the same pitch P) in the example of FIG. 2A or 3A (e.g., from the same design or photomask set). In some embodiments, an electrical line (or other structure) is in void 140 between transistors 100, and there is a greater distance between an adjacent structure and transistor 100 (e.g., sidewall 123) in the example of FIG. 3A than the corresponding distance (between an adjacent structure and transistor sidewall 123) in the example of FIG. 2A. This greater separation corresponds to yet lower capacitances. e.g., gate capacitances or effective capacitances, and higher performing circuits. For example, a first transistor 100 may have sidewall 123 beyond vertical and a slope of sidewall 123 of 91°, and the first transistor 100 (on a first substrate 199, e.g., first IC die) may be part of a ring oscillator that runs at a frequency 2% or greater than a ring oscillator (on a second IC die) with transistors 100 having a sidewall slope of 85°. In some embodiments, the ring oscillator on the first IC die has a frequency 3% greater than the ring oscillator on the second IC die.

FIG. 4B illustrates a cross-sectional plan view of transistor 100, including gate structure 120 with a yet shorter thickness T₂ of gate fill metal 122 and yet larger voids 140 and bottom CDs BCD between transistors 100. Notably, the view of FIG. 3B is taken at line A-A′ of FIG. 3A, through the lowest nanosheets 111, and may show the shortest thickness T₂. Larger voids 140 and bottom CDs BCD between transistors 100 again correspond to lower effective capacitances (and, e.g., high oscillator frequencies) and yet further tuned Vₜₕ.

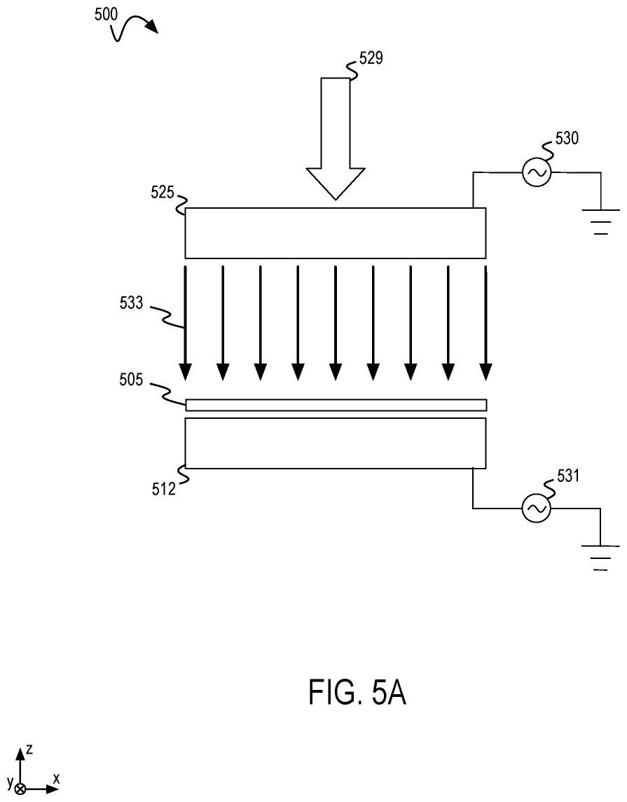

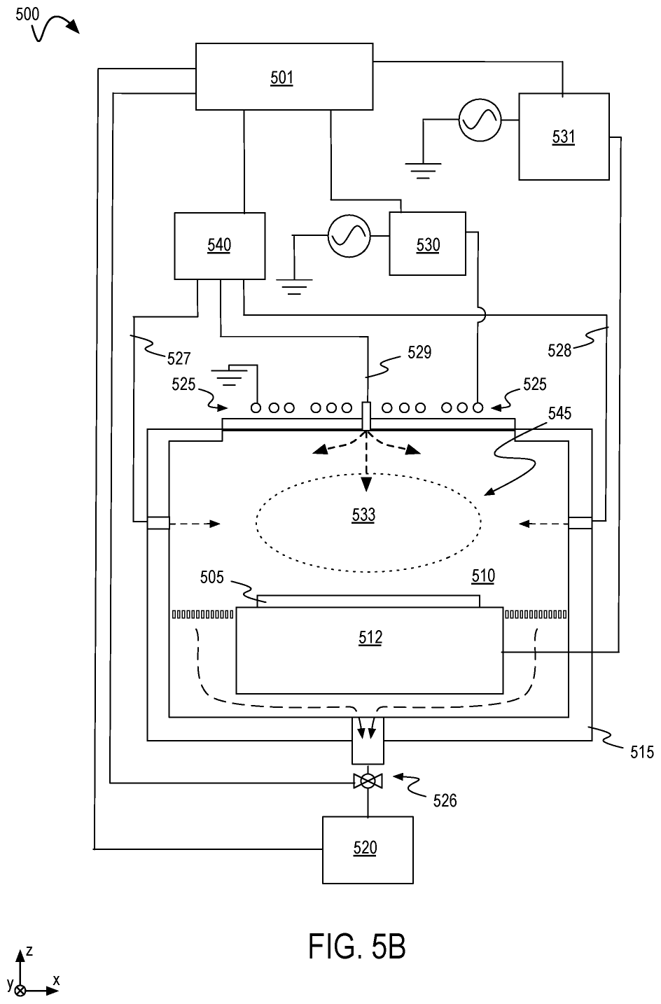

FIGS. 5A and 5B illustrate schematic views of an exemplary reactive plasma processing chamber 500, in accordance with some embodiments. FIG. 5A shows a simplified schematic view of processing chamber 500. FIG. 5B shows a more-detailed schematic view of processing chamber 500. Processing chamber 500 may be any appropriate reactor for etching microelectronics devices, such as a vacuum dry etch reactor, e.g., for practicing methods (or portions of methods) 600, 700, 800. Various components of processing chamber 500 are symbolically illustrated without necessarily illustrating the shape, size, location or other details of the various components. In the illustrated example, reactive processing chamber 500 is an etch process chamber, reactor, or module. Processing chamber 500 and the associated hardware may be of one or more process-compatible structural materials (e.g., aluminum, stainless steel, etc.).

As shown in the schematic view of FIG. 5A, workpiece 505 is coupled to a workpiece support assembly 512 in processing chamber 500. Gases are introduced into processing chamber 500 via a gas delivery line 529 for excitation into plasma 533 by one or more electrodes. Processing chamber 500 includes multiple electrodes and power sources 530, 531. Multiple electrodes may allow for improved development and control of plasma 533. Such control may also be improved by strategically locating the electrodes, e.g., above and below workpiece 505. Such control may also be improved by separately controlling the electrodes, e.g., with separate power sources. For example, upper electrode 525 is electrically coupled to an upper power source 530, and workpiece support assembly 512 (and its lower electrode) is electrically coupled to a lower power source 531. Upper electrode 525 and upper power source 530 develop a plasma 533 for processing a workpiece 505. Electrical excitation by lower power source 531 of workpiece support assembly 512 (and its lower electrode) may aid in control of a distribution of plasma 533. Upper and lower power sources 530, 531 may be any source, such as, but not limited to a radio frequency (RF), direct current (DC), or microwave generator. For example, in some embodiments, one of power sources 530, 531 are a DC source. In some embodiments, processing chamber 500 employs a capacitively coupled plasma (CCP) etch, and one or both of power sources 530, 531 are an RF source. In some embodiments, processing chamber 500 employs an inductively coupled plasma (ICP) or transformer coupled plasma (TCP) etch, and one or both of power sources 530, 531 are an RF source. In some embodiments, workpiece support assembly 512 does not use lower power source 531, and workpiece 505 is electrically insulated from workpiece support assembly 512. Each (or a single) power supply may energize multiple electrodes.

Discrete and separately controllable upper and lower power sources 530, 531 allow for adjusting, e.g., a plasma composition and a plasma distribution, for example, by separately adjusting the respective voltages and frequencies of power sources 530, 531. In some embodiments, both of power sources 530, 531 are RF sources, but at different operating frequencies. A higher frequency excitation near gas delivery line 529 may improve plasma formation. A lower frequency excitation of or near workpiece 505 may aid in control of a distribution of plasma 533 within processing chamber 500.

As illustrated in FIG. 5B, processing chamber 500 includes a chamber body 515 with a lid assembly including upper electrode 525 that is electrically coupled to upper power source 530. Upper electrode 525 is located at or near an upper end of chamber body 515, and workpiece support assembly 512 is at least partially disposed within a lower end of chamber body 515. Chamber body 515 may accommodate a slit valve opening to provide access to a workpiece processing region 510 where workpiece 505 is to reside during processing. The slit valve opening may be opened and closed to allow access to workpiece processing region 510, for example by handling robot (not shown). Workpiece 505 (e.g., a wafer including microelectronic device features) rests over a platen region of workpiece support assembly 512. Processing chamber 500 may include one or more heaters, for example, to adjust the temperature of workpiece 505 or reactive gases. Multiple heaters may be positioned in located separately in processing chamber 500, for example, above and below, or on multiple sides of workpiece 505. Such multizone heaters may also be controlled separately, e.g., to allow for a uniform etch across workpiece 505. A controller 501 may control one or more heaters, as well as power sources 530, 531 (which include bias and control circuitry), a vacuum system 520, a throttle valve 526, and a source gas manifold 540.

Processing chamber 500 is coupled to source gas manifold 540 that are to be introduced into a remote plasma region 545 by gas delivery line 529. Processing chamber 500 may include other gas delivery lines 527, 528 (and others, not shown) for delivery elsewhere into workpiece processing region 510. In the illustrated example, possible source gases include a hydrogen-containing precursor (e.g., methane (CH₄) or ammonia (NH₃)) and fluorocarbon precursor (e.g., CF₄, C₄F₈, etc.). Source gases may further include other gases, such as argon, or other reactive gases. Source gases are excited into plasma 533 by at least upper power source 530 and upper electrode 525, which includes multiple coils for an ICP or TCP etch in the example shown. In this example, remote plasma region 545 is contained within a lid assembly with the hydrogen source gas and fluorocarbon source gas to both flow into a remote plasma region 545. Reactive plasma effluents (e.g., chemical radicals) created within remote plasma region 545 are then to travel into workpiece processing region 510 where they interact with workpiece 505 (e.g., etching microelectronic features thereon). Processing chamber 500 may be pumped down below atmospheric pressure by a vacuum system 520 that includes a vacuum pump stack downstream of throttle valve 526 to regulate flow of gases through remote plasma region 545 and workpiece processing region 510.

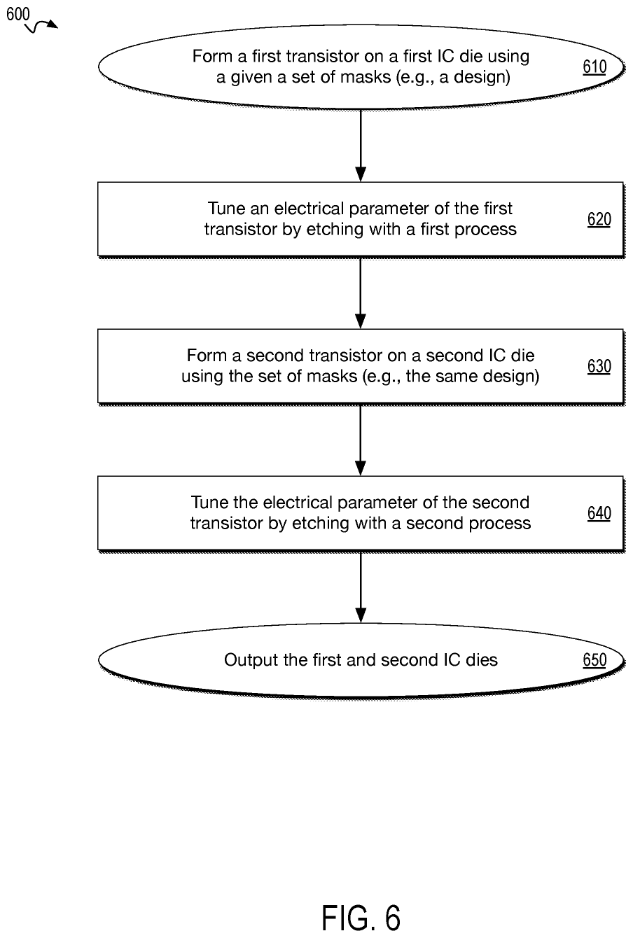

FIG. 6 is a flow chart of methods for tuning electrical parameters of transistors with metal gate structures, in accordance with some embodiments. Methods 600 include operations 610-650. Some operations shown in FIG. 6 are optional. Additional operations may be included. FIG. 6 shows an example sequence, but the operations can be done in other orders as well, and some operations may be omitted. Some operations can also be performed multiple times before other operations are performed. For example, multiple transistors may be tuned before outputting. Some operations may be included within other operations so that the number of operations illustrated FIG. 6 is not a limitation of the methods 600.

Methods 600 begin at operation 610, where a first transistor is formed on a first IC die. The transistor may be formed with a given set of masks, which may be referred to as a given design. The transistor may be at least partially formed using conventional methods, e.g., up to a stage of manufacture where the transistor has a gate structure available for etching. For example, the transistor may be formed as one of many transistors on an IC die, which may be one of multiple IC dies of a wafer. The IC die may be a substrate, much as described elsewhere herein, of semiconductor or insulator or any suitable material(s), such as a crystalline material of Si, Ge, SiGe, GaAs, GaN, Al₂O₃, SiC, etc. Substrate 199 may also include metals, dielectrics, dopants, and other materials commonly found in semiconductor substrates.

The transistor may be formed using the mask set, e.g., set of photolithographic masks or photomasks, which may be used conventionally for the manufacture of a single design or version of a product, e.g., as a template or pattern for the deposition, exposure, etching, etc., of the IC die (and wafer). The mask set may facilitate the forming of many transistors on the IC die concurrently with the formation of the first transistor. The transistor may be formed on the IC die with one or more channel regions (e.g., in one or more fins, nanoribbons, nanowires, or nanosheets) coupled to, and between, source and drain regions. A gate structure may be over the channel region(s) and may include an electrode of metal. The metal electrode may be over a dielectric layer or layers insulating the channel region(s) from the electrode. In embodiments having one or more channel regions in nanoribbons, nanowires, or nanosheets, the dielectric layer(s) may encircle the channel region(s), and the electrode may encircle the dielectric layer(s). The electrode may be exposed on an upper surface of the IC die, available for tuning by an etching process.

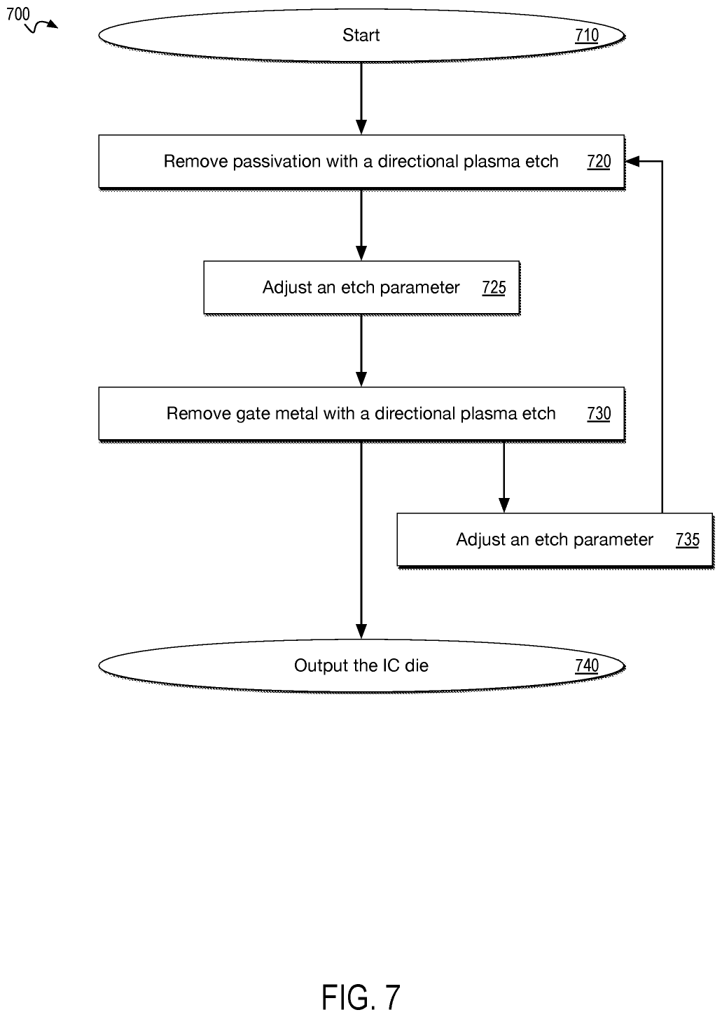

Methods 600 continue at operation 620, where an electrical parameter of the first transistor is tuned by etching the transistor's gate structure with a first process. The first process may be any suitable metal etch process, for example, as described at FIG. 7 and methods 700, which may produce a gate structure with a moderate sidewall slope (e.g., of 87° or less). The electrical parameter may be any such parameter sensitive to the etching, e.g., influenced by the size or shape of the transistor's gate structure, or by the orientation of transistor's gate structure relative to adjacent structures in the IC die. The electrical parameter, as well as the resultant gate structure, may be substantially as described elsewhere herein, e.g., at least at FIGS. 2A-4B. For example, a gate capacitance of the transistor may be tuned by etching a certain profile of the gate structure or by providing a certain separation between the gate structure and any adjacent structures in the IC die. A tuned gate capacitance of the transistor may cause a tuning of other parameters dependent on the transistor's gate capacitance, such as various frequencies, including an output frequency of a ring oscillator. Likewise, a Vₜₕ of the transistor may be tuned by etching a certain profile of the gate structure, as previously described, and other parameters dependent on the transistor's Vₜₕ, such as drive and leakage currents, may also be tuned.

Methods 600 continue at operation 630, where a second transistor is formed on a second IC die. The second transistor (and potentially other, multiple transistors on the second IC die and even wafer) may be at least partially formed much as the first transistor, e.g., with the same materials and design or mask set, and up to a stage of manufacture where the transistor has a gate structure available for etching. The use of the same mask set may, as is generally the case, result in similar structures with similar dimensions. For example, the second IC die may have one or more transistors adjacent to the second transistor with a same pitch between the first transistor and adjacent transistors as on the first IC die. The second transistor may have a gate structure similar or the same as the first transistor, e.g., with the same or similar metal layers and thicknesses, and similarly available for tuning by an etching process.

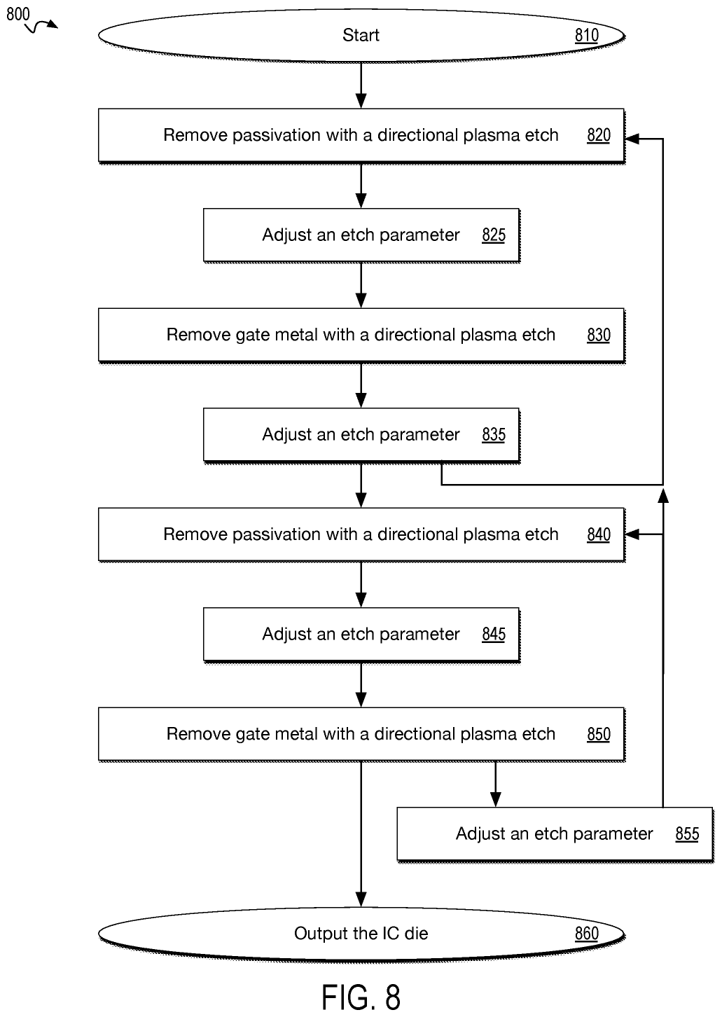

Methods 600 continue at operation 640, where the same electrical parameter of the second transistor is tuned by etching the second transistor's gate structure with a second process. The second process may be any suitable metal etch process, for example, as described at FIG. 8 and methods 800, which may produce a gate structure with a substantially vertical sidewall slope. Such a sidewall slope may be greater than, e.g., 87°, and may even be beyond vertical, e.g., up to 92° or more. The second process may share features with the first process (as described at FIG. 7 and methods 700). The second process may etch the second transistor's gate structure into a different profile and thereby provide a difference in electrical performance. The electrical parameter may be as previously described, e.g., at operation 620, as the second process may be used to tune the same electrical parameter, but to a different value (due to a different gate profile) on an otherwise identically manufactured transistor and IC die.

Methods 600 continue at operation 650, where the first and second IC dies are output from the first and second processes. The first and second IC dies may be completed, for example, by performing any subsequent processing on the dies, such that the first and second IC dies (or at least the first and second transistors) are electrically functional. Upon completion, the electrical performance of the first and second transistors (and first and second IC dies) may be measured and compared. The electrical parameter of the first and second transistors may differ due to the difference(s) between the first and second processes. In some embodiments, electrical parameter of the first transistor differs from the electrical parameter of the second transistor by more than 1.5%. For example, the second process may etch the second transistor's gate structure into a substantially vertical sidewall profile (e.g., with a slope elevation angle of 90° and depression angle of 0°). The second process may etch larger voids between the second transistor and adjacent transistors on the second IC die than between the first transistor and adjacent transistors on the first IC die. In some embodiments, the second transistor has a V_{th 20} mV less than a Vₜₕ of the first transistor, and the Vₜₕ of the second transistor is about 40% lower than the Vₜₕ of the first transistor. In some embodiments, the second transistor has gate capacitance 3% less than a gate capacitance of the first transistor. In some such embodiments, the second IC die has ring oscillator frequency 3% greater than a ring oscillator frequency of the first IC die.

FIG. 7 is a flow chart of methods 700 for etching a transistor's metal gate structure, in accordance with some embodiments. Any suitable etch process may be used. While well-controlled processes (such as an atomic layer etch (ALE)) may more readily etch a desired profile, less finely controlled but quicker processes may be suitable for some applications. In some embodiments, a certain profile is not required, or at least satisfactory gate profiles may have wide tolerances to unsatisfactory aspects. Methods 700 include operations 710-740, some of which are optional. Additional operations may be included. FIG. 7 shows an example sequence, but the operations can be done in other orders as well, and some operations may be omitted. Some operations can also be performed multiple times before other operations are performed. Some operations may be included within other operations so that the number of operations illustrated FIG. 7 is not a limitation of the methods 700.

Methods 700 begin at operation 710, the start of methods 700, which may include forming or receiving a transistor with a metal gate structure, such that the metal gate structure may be etched by operations in methods 700. The transistor and metal gate structure may be on an IC die and may be among many other transistors on the die, which may be part of a wafer to be etched.

Methods 700 continue at operation 720, where a passivation is removed with a directional plasma etch. The directionality of the etch may allow for breaking though targeted passivation, e.g., in a downward direction, orthogonal to an IC die and wafer, while leaving passivation substantially undisturbed on untargeted surfaces, e.g., sidewalls. The plasma etch may be performed within and by a plasma processing chamber as described elsewhere herein, for example, at least at FIGS. 5A and 5B. In some embodiments, the passivation-removal etch may occur in multiple operations, for example, modification and removal operations. The chamber may use one or more electrodes, and an upper electrode (e.g., having one or more ICP coils) may generate a reactive plasma. Any suitable chemistry may be employed to react with the passivation, such as a fluorocarbon or other reactive species. The plasma may enable sufficient reactions without high temperatures, which may be above, but may below, 100° C., depending on what is necessary for the given passivation layer and reactant chemistry. Similarly, with plasma, sufficient etching may occur after only a few seconds, even without high temperatures. In some embodiments, the upper electrode may be used at a relatively low RF power (e.g., 150 W) to generate a reactive plasma. In some embodiments, a lower electrode may assist in directing the plasma towards a wafer being etched.

Methods 700 continue at operation 725, where an etch parameter may be adjusted. The same or different values for various etch parameters may be used, such as values for chamber temperature and pressure, etch duration, excitation level (e.g., voltage and/or power) and frequency, chemistry, etc. While some parameter levels may be left unchanged, others may be adjusted to suit the next operation. For example, chemistry may be adjusted to match the material to be etched.

Methods 700 continue at operation 730, where gate metal is removed with a directional plasma etch, which may cut a metal gate structure and separate adjacent transistors. The directional plasma etch of operation 730 may share features with the directional plasma etch of operation 720. For example, the directional plasma etch may advantageously occur in the same processing chamber with similar conditions, such as temperature. A chemistry appropriate for etching metal may be different than the chemistry to etch the passivation layer at operation 720, and higher powers, e.g., RF powers, may be necessary for generating sufficiently reactive plasma for etching some gate structures. For example, a chlorine-based chemistry may react with the metal(s) of some gate structures, e.g., in an ALE process using another plasma gas for bombarding the chlorinated metal layer. In some embodiments, an upper electrode is energized by an RF power five or ten times greater than the RF power to the upper electrode at operation 720.

Methods 700 continue at either operation 735 or operation 740. At operation 735, an etch parameter may be adjusted before returning to operation 720 for removal of passivation with a directional plasma etch. The etch parameter adjustment(s) may restore chamber conditions to proper settings for passivation removal. Most of methods 700 may be repeated, if desired, starting with operation 720. Some or all of the operations of methods 700 may be repeated, as necessary, for example, to achieve a deeper etch into the metal gate structure.

Methods 700 may otherwise be completed at operation 740, where the IC die may be output, for example, after completing the etch of the transistor gate structure.

FIG. 8 is a flow chart of methods 800 for etching a transistor's metal gate structure, in accordance with some embodiments. Methods 800 may share features with methods 700. Any suitable etch process may be used, but well-controlled processes (such as an ALE) may be well-suited to methods 800, which may spend more processing time to produce a gate profile with improved electrical performance. For example, methods 800 may etch a metal gate structure to produce a substantially vertical transistor gate sidewall or a sidewall with a slope beyond vertical (e.g., with a negative depression angle from the vertical axis). Such profiles may be achieved with lower etch powers (e.g., upper electrode RF powers), but at higher etch temperatures and/or over longer etch durations. Methods 800 include operations 810-860. Some operations shown in FIG. 8 are optional. Additional operations may be included. FIG. 8 shows an example sequence, but the operations can be done in other orders as well, and some operations may be omitted. Some operations can also be performed multiple times before other operations are performed. Some operations may be included within other operations so that the number of operations illustrated FIG. 8 is not a limitation of the methods 800.

Methods 800 begin at operation 810, the start of methods 800, which may include forming or receiving a transistor with a metal gate structure, e.g., on an IC die and wafer to be etched.

Methods 800 continue at operation 820, where a passivation is removed with a directional plasma etch. The plasma etch may be as described at operation 720 of methods 700, e.g., performed in the plasma processing chamber of FIG. 5B. In some embodiments, this first iteration of the passivation-removal etch employs identical process parameters matched to the passivation-removal etch at operation 720. In other embodiments, the upper electrode is energized with a lower RF power than at operation 720. In some such embodiments, the chamber temperature and pressure, as well as the etch duration, are maintained at levels of methods 700.

Methods 800 continue at operation 825, where an etch parameter may be adjusted. Some etch parameter settings may be kept constant, while others may be adjusted to suit the next operation. For example, chemistry may be adjusted to match the material to be etched. In some embodiments, an upper electrode RF power may be increased, e.g., to etch a metal gate structure.

Methods 800 continue at operation 830, where gate metal is removed with a directional plasma etch. The directional plasma etch of operation 830 may share features with the directional plasma etch of operation 730. For example, in some embodiments, the directional plasma etch of operation 830 (unlike operation 850) has identical etch conditions as the directional plasma etch of operation 730, including the same etch chemistry, upper electrode RF power, chamber temperature and pressure, and etch duration.

Methods 800 continue at either operation 835 or operation 840. At operation 835, an etch parameter may be adjusted before returning to operation 820 for removal of passivation with a directional plasma etch. The etch parameter adjustment(s) may restore chamber conditions to proper settings for passivation removal. Most of methods 800 may be repeated, if desired, starting with operation 820. Some or all of the operations of methods 800 may be repeated to achieve a deeper etch into the metal gate structure. In some embodiments, operations 820-835 are repeated multiple times before proceeding on to operation 840, etc.

Methods 800 continue at operation 840, where a passivation is removed with a directional plasma etch. The plasma etch of operation 840 may be similar to operation 820, e.g., with a same chemistry and upper electrode RF power, but operation 840 may be at an elevated chamber temperature (for example, up to 50° C. greater than at operation 820) and be for a longer duration (for example, up to 20 seconds). In some embodiments, the upper electrode is energized as in operation 820, but that energization is with the reduced RF power, to a lower RF power than at operation 720.

Operations 840, 850 may be similar to operations 820, 830, respectively, with only process parameters (or a single process parameter) adjusted, much as could be done at operations 825, 835. The various operations of methods 800 are split as they are in FIG. 8 to show how some different operations (e.g., operations 840, 850) may be grouped and repeated or interspersed between same operations (e.g., operations 820, 830) to achieve different gate profiles and electrical performances.

Methods 800 continue at operation 845, where an etch parameter may be adjusted. Some etch parameters, such as chemistry and upper electrode RF power, may be altered or increased to etch a metal gate structure. The elevated temperatures of operation 840 (e.g., relative to operations 820, 830 and operations 720, 730 of methods 700) may be maintained for operation 850.

Methods 800 continue at operation 850, where gate metal is removed with a directional plasma etch. The metal etch of operation 850 may share features with the metal etch of operation 830, for example, an elevated upper electrode RF power, but this RF power is reduced relative to that of operation 830. In some embodiments, the upper electrode RF power of operation 850 (while greater than in the passivation removal operations 820, 840) is 500 W lower than the upper electrode RF power of operation 830 (or operation 730 of methods 700). The etch duration may return to the few seconds of most operation prior to the increased duration of operation 840.

Methods 800 continue at either operation 855 or operation 860. At operation 855, an etch parameter may be adjusted before returning to operation 840 (to repeat the second half of methods 800) or 820 (to repeat the first half of methods 800) to remove passivation with a directional plasma etch. The etch parameter adjustment(s) may restore chamber conditions to proper settings for passivation removal. Some or all of the operations of methods 800 may be repeated, if necessary.

Methods 800 may otherwise be completed at operation 860, where the IC die may be output, for example, after completing the etch of the transistor gate structure.

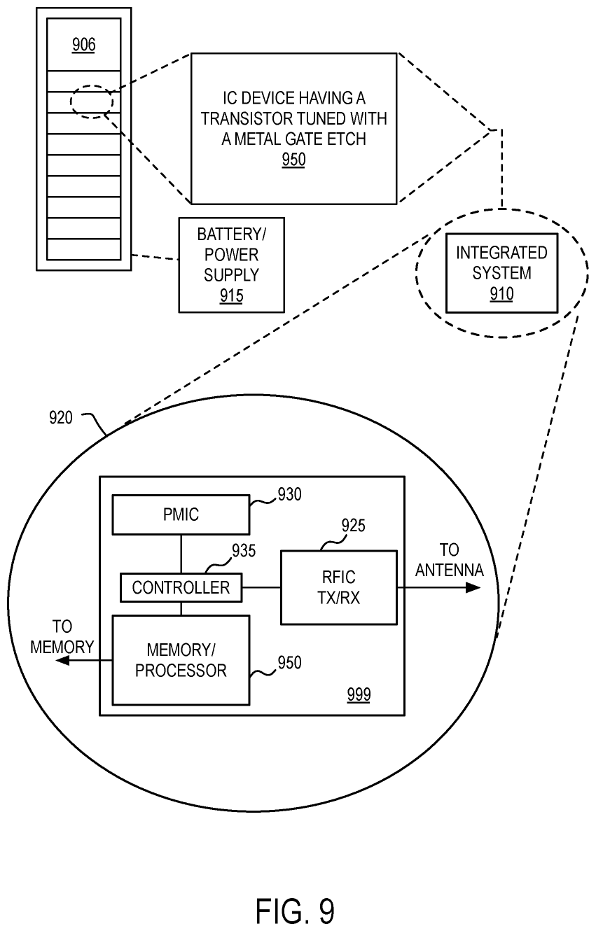

FIG. 9 illustrates a diagram of an example data server machine 906 employing an IC device having a transistor tuned with a metal gate etch, in accordance with some embodiments. Server machine 906 may be any commercial server, for example, including any number of high-performance computing platforms disposed within a rack and networked together for electronic data processing, which in the exemplary embodiment includes one or more devices 950 having a transistor tuned with a metal gate etch.

Also as shown, server machine 906 includes a battery and/or power supply 915 to provide power to devices 950, and to provide, in some embodiments, power delivery functions such as power regulation. Devices 950 may be deployed as part of a package-level integrated system 910. Integrated system 910 is further illustrated in the expanded view 920. In the exemplary embodiment, devices 950 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 950 is a microprocessor including a static RAM (SRAM) cache memory. As shown, device 950 may be an IC device having a transistor tuned with a metal gate etch, as discussed herein. Device 950 may be further coupled to (e.g., communicatively coupled to) a board, an interposer, or a substrate 999 along with, one or more of a power management IC (PMIC) 930, RF (wireless) IC (RFIC) 925 including a wideband RF (wireless) transmitter and/or receiver (TX/RX) (e.g., including a digital baseband and an analog front end module further includes a power amplifier on a transmit path and a low noise amplifier on a receive path), and a controller 935 thereof. In some embodiments, RFIC 925, PMIC 930, controller 935, and device 950 include a transistor tuned with a metal gate etch.

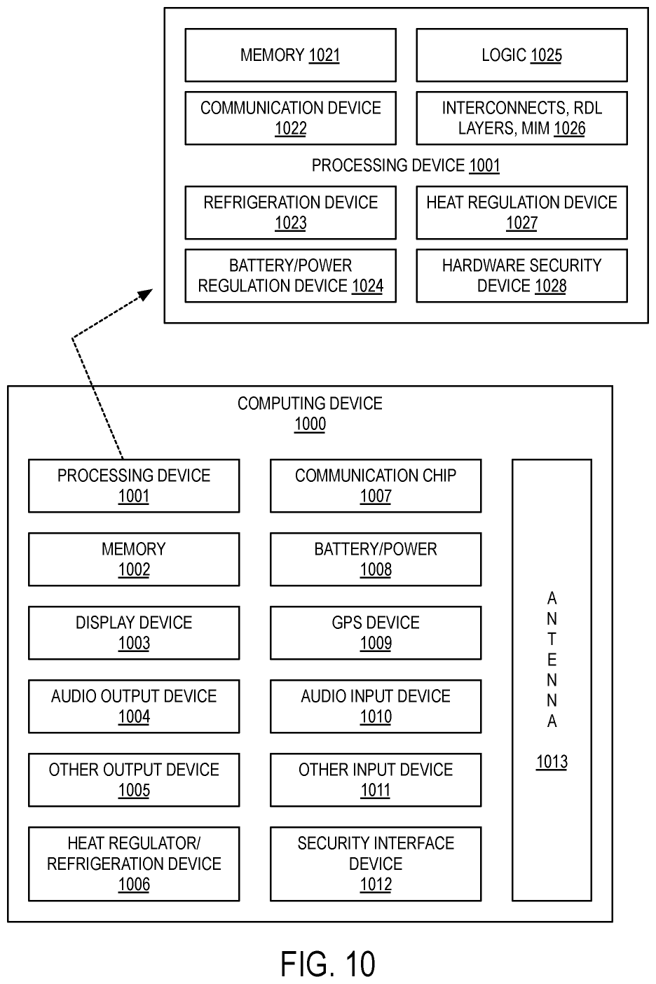

FIG. 10 is a block diagram of an example computing device 1000, in accordance with some embodiments. For example, one or more components of computing device 1000 may include any of the devices or structures discussed herein. A number of components are illustrated in FIG. 10 as being included in computing device 1000, but any one or more of these components may be omitted or duplicated, as suitable for the application. In some embodiments, some or all of the components included in computing device 1000 may be attached to one or more printed circuit boards (e.g., a motherboard). In some embodiments, various ones of these components may be fabricated onto a single system-on-a-chip (SoC) die. Additionally, in various embodiments, computing device 1000 may not include one or more of the components illustrated in FIG. 10, but computing device 1000 may include interface circuitry for coupling to the one or more components. For example, computing device 1000 may not include a display device 1003, but may include display device interface circuitry (e.g., a connector and driver circuitry) to which display device 1003 may be coupled. In another set of examples, computing device 1000 may not include an audio output device 1004, other output device 1005, global positioning system (GPS) device 1009, audio input device 1010, or other input device 1011, but may include audio output device interface circuitry, other output device interface circuitry, GPS device interface circuitry, audio input device interface circuitry, audio input device interface circuitry, to which audio output device 1004, other output device 1005, GPS device 1009, audio input device 1010, or other input device 1011 may be coupled.

Computing device 1000 may include a processing device 1001 (e.g., one or more processing devices). As used herein, the term “processing device” or “processor” indicates a device that processes electronic data from registers and/or memory to transform that electronic data into other electronic data that may be stored in registers and/or memory. Processing device 1001 may include a memory 1021, a communication device 1022, a refrigeration device 1023, a battery/power regulation device 1024, logic 1025, interconnects 1026 (i.e., optionally including redistribution layers (RDL) or metal-insulator-metal (MIM) devices), a heat regulation device 1027, and a hardware security device 1028.

Processing device 1001 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1000 may include a memory 1002, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1002 includes memory that shares a die with processing device 1001. This memory may be used as cache memory and may include embedded dynamic random-access memory (eDRAM) or spin transfer torque magnetic random-access memory (STT-MRAM).

Computing device 1000 may include a heat regulation/refrigeration device 1006. Heat regulation/refrigeration device 1006 may maintain processing device 1001 (and/or other components of computing device 1000) at a predetermined low temperature during operation.

In some embodiments, computing device 1000 may include a communication chip 1007 (e.g., one or more communication chips). For example, the communication chip 1007 may be configured for managing wireless communications for the transfer of data to and from computing device 1000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 1007 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1007 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1007 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1007 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1007 may operate in accordance with other wireless protocols in other embodiments. Computing device 1000 may include an antenna 1013 to facilitate wireless communications and/or to receive other wireless communications (such as AM or FM radio transmissions).

In some embodiments, communication chip 1007 may manage wired communications, such as electrical, optical, or any other suitable communication protocols (e.g., the Ethernet). As noted above, communication chip 1007 may include multiple communication chips. For instance, a first communication chip 1007 may be dedicated to shorter-range wireless communications such as Wi-Fi or Bluetooth, and a second communication chip 1007 may be dedicated to longer-range wireless communications such as GPS, EDGE, GPRS, CDMA, WiMAX, LTE, EV-DO, or others. In some embodiments, a first communication chip 1007 may be dedicated to wireless communications, and a second communication chip 1007 may be dedicated to wired communications.

Computing device 1000 may include battery/power circuitry 1008. Battery/power circuitry 1008 may include one or more energy storage devices (e.g., batteries or capacitors) and/or circuitry for coupling components of computing device 1000 to an energy source separate from computing device 1000 (e.g., AC line power).

Computing device 1000 may include a display device 1003 (or corresponding interface circuitry, as discussed above). Display device 1003 may include any visual indicators, such as a heads-up display, a computer monitor, a projector, a touchscreen display, a liquid crystal display (LCD), a light-emitting diode display, or a flat panel display, for example.

Computing device 1000 may include an audio output device 1004 (or corresponding interface circuitry, as discussed above). Audio output device 1004 may include any device that generates an audible indicator, such as speakers, headsets, or earbuds, for example.

Computing device 1000 may include an audio input device 1010 (or corresponding interface circuitry, as discussed above). Audio input device 1010 may include any device that generates a signal representative of a sound, such as microphones, microphone arrays, or digital instruments (e.g., instruments having a musical instrument digital interface (MIDI) output).

Computing device 1000 may include a GPS device 1009 (or corresponding interface circuitry, as discussed above). GPS device 1009 may be in communication with a satellite-based system and may receive a location of computing device 1000, as known in the art.

Computing device 1000 may include other output device 1005 (or corresponding interface circuitry, as discussed above). Examples of the other output device 1005 may include an audio codec, a video codec, a printer, a wired or wireless transmitter for providing information to other devices, or an additional storage device.

Computing device 1000 may include other input device 1011 (or corresponding interface circuitry, as discussed above). Examples of the other input device 1011 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1000 may include a security interface device 1012. Security interface device 1012 may include any device that provides security measures for computing device 1000 such as intrusion detection, biometric validation, security encode or decode, access list management, malware detection, or spyware detection.

Computing device 1000, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-10. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, one or more apparatuses include a first transistor including a first stack of nanosheets or nanowires through a first gate structure, wherein a first sidewall of the first gate structure has a first slope, and a second transistor including a second stack of nanosheets or nanowires through a second gate structure, wherein a second sidewall of the second gate structure has a second slope that differs from the first slope by at least five degrees.

In one or more second embodiments, further to the first embodiments, a first integrated circuit (IC) die includes the first transistor, and a second IC die includes the second transistor.

In one or more third embodiments, further to the first or second embodiments, the first IC die has a first oscillator frequency greater than a second oscillator frequency of the second IC die.

In one or more fourth embodiments, further to the first through third embodiments, the first transistor has a first threshold voltage less than a second threshold voltage of the second transistor.

In one or more fifth embodiments, further to the first through fourth embodiments, the first slope is within two degrees of vertical.

In one or more sixth embodiments, further to the first through fifth embodiments, the first slope has a depression angle from vertical of less than 0 degrees.

In one or more seventh embodiments, further to the first through sixth embodiments, a first nearest sidewall is a first distance to the first sidewall, a second nearest sidewall is a second distance to the second sidewall, and the second distance is greater than the first distance.

In one or more eighth embodiments, one or more apparatuses include a first pair of adjacent transistors, including first and second stacks of nanosheets or nanowires through first and second gate structures and a first taper, wherein the first taper is a first difference between a first upper distance and a first lower distance between the first and second gate structures, and a second pair of adjacent transistors, including third and fourth stacks of nanosheets or nanowires through third and fourth gate structures and a second taper, wherein the second taper is a second difference between a second upper distance and a second lower distance between the second gate structures, and the second taper is at least five times the first taper.

In one or more ninth embodiments, further to the eighth embodiments, a first integrated circuit (IC) die includes the first pair of adjacent transistors, and a second IC die includes the second pair of adjacent transistors.

In one or more tenth embodiments, further to the eighth or ninth embodiments, the first IC die has a first oscillator frequency greater than a second oscillator frequency of the second IC die.

In one or more eleventh embodiments, further to the eighth through tenth embodiments, a first capacitance between the first pair of adjacent transistors is less than a second capacitance between the second pair of adjacent transistors.

In one or more twelfth embodiments, further to the eighth through eleventh embodiments, a first pitch between the first and second stacks is approximately equal to a second pitch between the third and fourth stacks.

In one or more thirteenth embodiments, further to the eighth through twelfth embodiments, the first taper is less than 5 nm.

In one or more fourteenth embodiments, a method includes forming, with a set of masks, a first transistor on a first integrated circuit (IC) die, tuning an electrical parameter of the first transistor by etching a first gate structure of the first transistor with a first process, forming, with the set of masks, a second transistor on a second IC die, tuning the electrical parameter of the second transistor by etching a second gate structure of the second transistor with a second process, and outputting the first and second IC dies, wherein the electrical parameter of the first transistor differs from the electrical parameter of the second transistor by more than 1.5%.

In one or more fifteenth embodiments, further to the fourteenth embodiments, the first and second processes include a directional plasma etch, and the directional plasma etch of the second process etches the second gate structure with at least one of a plurality of process parameters adjusted from the directional plasma etch of the first process, wherein the plurality of process parameters include a radio frequency (RF) power, a temperature, and a duration.

In one or more sixteenth embodiments, further to the fourteenth or fifteenth embodiments, the directional plasma etch of the second process etches the second gate structure with a lower RF power, a higher temperature, or a longer duration.

In one or more seventeenth embodiments, further to the fourteenth through sixteenth embodiments, the second process etches the second gate structure with all of the process parameters matched to the directional plasma etch of the first process before etching the second gate structure with at least one of the plurality of process parameters adjusted from the directional plasma etch of the first process.

In one or more eighteenth embodiments, further to the fourteenth through seventeenth embodiments, the first and second processes each include first and second directional plasma etches, the first directional plasma etch removing passivation over the first or second gate structure, and the second directional plasma etch removing a gate metal of the first or second gate structure.

In one or more nineteenth embodiments, further to the fourteenth through eighteenth embodiments, the electrical parameter is an oscillator frequency or a threshold voltage, and the oscillator frequency of the second IC die is at least 1.5% greater than the oscillator frequency of the first IC die, or the threshold voltage of the first transistor is at least 1.5% greater than the threshold voltage of the second transistor.

In one or more twentieth embodiments, further to the fourteenth through nineteenth embodiments, the second process etches the second gate structure to form a sidewall having a slope fewer than two degrees from vertical.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. One or more apparatuses, comprising:
a first transistor comprising a first stack of nanosheets or nanowires through a first gate structure, wherein a first sidewall of the first gate structure has a first slope; and
a second transistor comprising a second stack of nanosheets or nanowires through a second gate structure, wherein a second sidewall of the second gate structure has a second slope that differs from the first slope by at least five degrees.

2. The one or more apparatuses of claim 1, wherein a first integrated circuit (IC) die comprises the first transistor, and a second IC die comprises the second transistor.

3. The one or more apparatuses of claim 2, wherein the first IC die has a first oscillator frequency greater than a second oscillator frequency of the second IC die.

4. The one or more apparatuses of claim 1, wherein the first transistor has a first threshold voltage less than a second threshold voltage of the second transistor.

5. The one or more apparatuses of claim 1, wherein the first slope is within two degrees of vertical.

6. The one or more apparatuses of claim 1, wherein the first slope has a depression angle from vertical of less than 0 degrees.

7. The one or more apparatuses of claim 1, wherein a first nearest sidewall is a first distance to the first sidewall, a second nearest sidewall is a second distance to the second sidewall, and the second distance is greater than the first distance.

8. One or more apparatuses, comprising:
a first pair of adjacent transistors, comprising first and second stacks of nanosheets or nanowires through first and second gate structures and a first taper, wherein the first taper is a first difference between a first upper distance and a first lower distance between the first and second gate structures; and
a second pair of adjacent transistors, comprising third and fourth stacks of nanosheets or nanowires through third and fourth gate structures and a second taper, wherein the second taper is a second difference between a second upper distance and a second lower distance between the second gate structures, and the second taper is at least five times the first taper.

9. The one or more apparatuses of claim 8, wherein a first integrated circuit (IC) die comprises the first pair of adjacent transistors, and a second IC die comprises the second pair of adjacent transistors.

10. The one or more apparatuses of claim 9, wherein the first IC die has a first oscillator frequency greater than a second oscillator frequency of the second IC die.

11. The one or more apparatuses of claim 8, wherein a first capacitance between the first pair of adjacent transistors is less than a second capacitance between the second pair of adjacent transistors.

12. The one or more apparatuses of claim 8, wherein a first pitch between the first and second stacks is approximately equal to a second pitch between the third and fourth stacks.

13. The one or more apparatuses of claim 8, wherein the first taper is less than 5 nm.

14. A method, comprising:
forming, with a set of masks, a first transistor on a first integrated circuit (IC) die;
tuning an electrical parameter of the first transistor by etching a first gate structure of the first transistor with a first process;
forming, with the set of masks, a second transistor on a second IC die;
tuning the electrical parameter of the second transistor by etching a second gate structure of the second transistor with a second process; and
outputting the first and second IC dies, wherein the electrical parameter of the first transistor differs from the electrical parameter of the second transistor by more than 1.5%.

15. The method of claim 14, wherein the first and second processes comprise a directional plasma etch, and the directional plasma etch of the second process etches the second gate structure with at least one of a plurality of process parameters adjusted from the directional plasma etch of the first process, wherein the plurality of process parameters comprise a radio frequency (RF) power, a temperature, and a duration.

16. The method of claim 15, wherein the directional plasma etch of the second process etches the second gate structure with a lower RF power, a higher temperature, or a longer duration.

17. The method of claim 15, wherein the second process etches the second gate structure with all of the process parameters matched to the directional plasma etch of the first process before etching the second gate structure with at least one of the plurality of process parameters adjusted from the directional plasma etch of the first process.

18. The method of claim 14, wherein the first and second processes each comprise first and second directional plasma etches, the first directional plasma etch removing passivation over the first or second gate structure, and the second directional plasma etch removing a gate metal of the first or second gate structure.

19. The method of claim 14, wherein the electrical parameter is an oscillator frequency or a threshold voltage, and the oscillator frequency of the second IC die is at least 1.5% greater than the oscillator frequency of the first IC die, or the threshold voltage of the first transistor is at least 1.5% greater than the threshold voltage of the second transistor.

20. The method of claim 14, wherein the second process etches the second gate structure to form a sidewall having a slope fewer than two degrees from vertical.
